(19) United States
(12) Patent Application Publication
(10) Pub. No.: US 2009/0140261 A1
(43) Pub. Date: Jun. 4, 2009

(54) MOS SOLID-STATE IMAGE DEVICE AND METHOD OF MANUFACTURING THE SAME

(75) Inventor: Kosaku Saeki, Toyama (JP)

Correspondence Address: STEPTOE & JOHNSON LLP, 1330 CONNECTICUT AVE., NW, WASHINGTON, DC, 20036, US

(73) Assignee: Panasonic Corporation, Kadoma-shi (JP)

(21) Appl. No.: 12/326,249

(22) Filed: Dec. 2, 2008

(30) Foreign Application Priority Data
Dec. 3, 2007 (JP) 2007-311852

(51) Int. Cl. H01L 31/112; H01L 31/18

(52) U.S. Cl. 257/72; 438/73; 257/E31.073; 257/E21.158

(57) ABSTRACT

A sidewall film 121 in a digital portion has a multilayer structure including at least an offset sidewall film 107b located inside. An extension diffusion layer 110 is formed adjacent to a source/drain diffusion region 111 through the offset sidewall film 107b and a gate electrode 102 as a mask. Thus, an operation speed of the digital portion can be increased with a manufacturing process controlled. For a pixel portion, an antireflection film 122 of a laminate structure is formed simultaneously with formation of the sidewall film 121. Thus, the antireflection film thickness can be optimized with the manufacturing process controlled. As a result, a high sensitive MOS solid-state image device can be provided.

### FIELD OF THE INVENTION

The present invention relates to a MOS (Metal Oxide Semiconductor) solid-state image device including a digital portion (peripheral circuit) and a pixel portion mixedly mounted therein so as to make up a system on chip, and a method of manufacturing the same.

### BACKGROUND OF THE INVENTION

As a solid-state image device, a CCD (Charge Coupled Device) solid-state image device has been conventionally known. The CCD solid-state image device sequentially transfers signal charges generated in photodiodes via adjacent pixels to output image signals. Although not suitable for an increased operation speed, this structure can utilize dedicated processes optimized for manufacture of the CCD solid-state image device, enabling formation of a high sensitive photodiode with low dark output (low dark current). Thus, the CCD solid-state image device can provide pixels with a high S/N ratio and has been commonly used for cameras and the like, taking advantage of the above-described features.

However, in recent years, a requirement for resolution of motion pictures of cameras has led to a demand for enhancement of the speed aspect of image pickup capabilities and thus a demand for an increase in the operation speed of the solid-state image device. Amplified solid-state image devices typified by a MOS solid-state image device are expected to meet these demands. Unlike the CCD solid-state image device, the amplified solid-state image device allows for an increase in an operation speed as a result of the structure thereof which eliminates the need to sequentially transfer signal charges and extracts image signals directly from individual pixels.

The MOS solid-state image device also enables peripheral circuits (logic portions including an A/D converter and a shift register and circuits for image processing, camera processing, and input and output) and pixel portions to be integrated into a system on chip. The MOS solid-state image device can thus advantageously be used for electronic information equipment such as a video camera and a cellular phone with a digital camera which require an increase in the operation speed of the peripheral transistor.

However, in recent years, in connection with manufacture of the MOS solid-state image device in the form of a system on chip, the gate length of a gate electrode has been increasingly reduced in response to a demand for a faster operation of a digital circuit portion. When a conventional CMOS logic process is used without being modified, simply performing conventional LDD (Lightly Doped Drain) implantation and source/drain implantation subsequent to formation of SWs (Sidewalls) may spread a diffusion layer in a channel direction to seriously degrade a short channel characteristic, in association with the reduced gate length of the gate electrode. Furthermore, for the pixel portion, no measure has been taken for the sensitivity of and the dark output (dark current) from the photodiode unlike in the case of the above-described CCD processes. This disadvantageously reduces the S/N ratio of pixels. Thus, the most important challenges for the MOS solid-state image device are an increase in the sensitivity of and a reduction in the dark output from the photodiode.

FIG. 3 is a schematic sectional view of a conventional MOS solid-state image device, showing a transistor structure making up the LDD and the SW of the CMOS logic portion of the digital portion according to the conventional art. Here, the structure of an n-channel MOSFET (Metal-Oxide-Semiconductor Field Effect Transistor) will be described by way of example.

In FIG. 3, a gate insulating film 201 and a gate electrode 202 are formed on a substrate 200 in this order from below. A sidewall film 221 made up of a silicon oxide film is formed as a sidewall of the gate electrode. Before formation of the sidewall film 221, an LDD diffusion region 204c is formed by implanting phosphorous or arsenic through the gate electrode 202 as a mask. Thereafter, a source/drain diffusion layer 211 is formed through the gate electrode 202 and the sidewall film 221 as a mask. The remaining part of the technique is well-known and will thus not be described below.

Now, the structure of the conventional MOS solid-state image device in the pixel portion will be described with reference to FIG. 3.

A pixel shown in FIG. 3 includes a photodiode 203 (hereinafter referred to as a light receiving portion 203), and three transistors, a transferring transistor 231, an amplifying transistor 232, and a resetting transistor 233 (these components are hereinafter appropriately referred to as active elements). The transferring transistor 231 transfers signal charges from the light receiving portion 203 to a detection portion 204a. The amplifying transistor 232 outputs a signal corresponding to the potential of the detection portion 204a. The resetting transistor 233 resets the potential of the detection portion 204a varied by the signal charges, to an initial value.

As shown in FIG. 3, the transferring transistor 231 is composed of the light receiving portion 203, which is an N-type impurity diffusion region formed in the silicon substrate 200, the detection portion 204a, which is an N-type impurity diffusion region formed at a predetermined distance from the light receiving portion 203, and a gate electrode (hereinafter referred to as a transfer gate electrode 202a) formed on a surface of the silicon substrate 200 between the two impurity diffusion regions via the silicon oxide film 201, which is a gate insulating film. Here, the light receiving portion 203 makes up a source of the transferring transistor 231. The detection portion 204a makes up a drain of the transferring transistor 231.

In an example in FIG. 3, the transferring transistor 231 has an LDD structure that mitigates concentration of electric fields at an end of the detection portion 204a which has a high impurity concentration. That is, an LDD diffusion region 204b with a lower impurity concentration than the detection portion 204a is provided on a light receiving portion 203 side of the detection portion 204a.

As is well known, such an LDD structure is formed by first ion implantation through the transfer gate electrode 202a and an isolation portion 206 as a mask and second ion implantation through the sidewall film 221, the transfer gate electrode 202a, and the isolation portion 206 as a mask. The first ion implantation involves a dose corresponding to the concentration of impurities in the LDD diffusion region 204b. The second ion implantation involves a dose corresponding to the concentration of impurities in the detection portion 204a.

The isolation portion 206 is a field oxide film provided by STI (Shallow Trench Isolation) or the like in order to electrically separate the pixels and active elements from one another. In the example in FIG. 3, the light receiving portion 203 has a buried diode structure in which a surface P-type layer 205 that is a P-type impurity region with a high impurity concentration is provided near a surface of the silicon substrate 200.

Moreover, for convenience, the drawings show terminals 241, 242, and 243. However, in the actual MOS solid-state image device, these terminals are connected to wires coupling the pixels together. Here, reference numeral 241 denotes an output terminal through which signals from the amplifying transistor 232 are output. Reference numeral 242 denotes a power supply terminal through which a power supply potential is supplied to the amplifying transistor 232 and the resetting transistor 233. Reference numeral 243 denotes a control terminal to which a control signal is input which allows signal charges accumulated in the detection portion 204a to be discharged to the power supply terminal 242 side every constant period.

In the conventional MOS solid-state image device, the silicon oxide film serving as the gate insulating film 201 in the transferring transistor 231 is normally formed by a thermal oxidation method of oxidizing the entire surface of the silicon substrate 200. Thus, the silicon oxide film is formed not only on the surface of the silicon substrate immediately below the transfer gate electrode 202a but also on the surface of the silicon substrate in the light receiving portion 203.

In the light receiving portion 203 having such a structure, the refractive index (n_{Si}=about 3.5) of the silicon substrate 200 is different from that (n_{SiO2}=about 1.45) of the silicon oxide film. Light entering the light receiving portion 203 is partly reflected, by an interface between the silicon substrate 200 and the silicon oxide film (the surface of the silicon substrate 200), toward the silicon oxide film and emitted to the exterior of the solid-state image device. Thus, the quantity of light reaching the light receiving portion 203 disadvantageously decreases to reduce the sensitivity of the pixels.

To solve this problem, a structure has been proposed in which an antireflection film is provided on the light receiving portion 203. FIG. 4 is a schematic sectional view showing the structure of a conventional MOS solid-state image device including an antireflection film.

As shown in FIG. 4, the antireflection film 222 is formed on the gate insulating film 201. Here, to allow the light receiving portion 203 to be reliably covered, an end of the antireflection film 222 is provided on the gate electrode 202a and also on the isolation portion 206, formed around the outer periphery of the light receiving portion 203. The structure of the MOS solid-state image device except for the antireflection film 222 is the same as that of the MOS solid-state image device shown in FIG. 3.

In general, the antireflection film 222 is composed of a material with a refractive index that is lower than that of the silicon substrate 200 and higher than that of the gate insulating film 201, for example, a silicon oxide film. Such materials include, for example, a silicon nitride film, a silicon oxynitride film, a titanium oxide film, and a tantalum oxide film. In this case, as the antireflection film 222, a silicon nitride film (n_{SiNx}=2.0) is formed by a CVD (Chemical Vapor Deposition) method.

Thus, by providing the antireflection film 222 made up of a silicon nitride film on the insulating film 201, light reflected by the surface of the silicon substrate 200 is reflected toward the silicon substrate 200 by an interface between the silicon oxide film 201 and the silicon nitride film 222. This enables a reduction in the rate at which light reflected by the surface of the silicon substrate 200 is emitted to the exterior.

In both of the solid-state image devices in FIGS. 3 and 4, an interlayer insulating film made up of a silicon oxide film or the like is formed on the top surface thereof. A light blocking film, a passivation film, or the like is formed on the interlayer insulating film; the light blocking film prevents light from entering the entire area of the interlayer insulating film except for the light receiving portion 203, and the passivation film is made up of a silicon nitride film to prevent possible entry of moisture or the like.

### DISCLOSURE OF THE INVENTION

With the increased operation speed and improved image quality of the MOS solid-state image device in the form of a system on chip, for the digital portion, the gate length has been reduced. For the pixel portion, the dedicated process optimized for the manufacture of the CCD solid-state image device is used, and efforts have been made to miniaturize design rules for the isolation portion and the wiring portion.

In particular, characteristics of the peripheral circuit in the digital portion are such that relevant transistors need to operate at high speeds. Thus, a saturation current (Ids) needs to be increased. The saturation current is normally given by the formula Ids=(½)×(W/L)×μeff×εox×(Sox/tox)×(Vg−Vth), where the parameters are W: gate width, L: gate length, μeff: effective mobility, εox: gate insulating film dielectric constant, Sox: gate area, tox: gate film thickness, Vg: gate voltage; and Vth: threshold voltage. To increase the saturation current, the gate length (L) or the gate film thickness is reduced. As a result, the operation speed is increased.

Thus, when the gate electrode is formed simply by the LDD implantation and the source/drain implantation subsequent to the SW formation using a design rule of 0.13 um or less as in the case of conventional techniques, the diffusion layer spreads in the channel direction to significantly degrade the short channel characteristic.

A factor degrading the reliability of the MOS transistor in connection with the miniaturization is implantation of hot carriers into the gate insulating film. The reduced gate length intensifies an electric field acting in a direction along a channel region between the source and the drain. The electric field accelerates carriers present in the channel region. The carriers are thus provided with high energy. Such carriers are called hot carriers and injected into the gate insulating film beyond an energy barrier at the interface between the semiconductor substrate and the gate insulating film. As a result, disadvantageously, the hot carriers generate an interface level to change the threshold voltage of the semiconductor, thus degrading a current driving capability of the MOS transistor.

Next, for the pixel portion, the sensitivity characteristic needs to be enhanced in order to improve the image quality. To achieve this, an antireflection film having an optimum thickness needs to be formed on the photodiode. To maximize the effects of the antireflection film, the antireflection film needs to be appropriately designed according to a wavelength at which reflection is prevented.

For example, most strictly inhibiting reflection of light with a central wavelength of 550 nm is important in obtaining an antireflection film with spectral characteristics that are relatively flat within a visible light region (380 to 780 nm). In this case, an optical distance satisfying a reflectance reduction condition expressed by m+λ/4 (m: natural number) is m+137.5 nm. Here, since the refractive index of a silicon oxide film is n_{SiO2}=1.45 and the refractive index of a silicon nitride film is n_{SiNx}=2.0, the reflection of the 550-nm light can be inhibited by selecting a combination of film thicknesses satisfying the condition “the film thickness of the silicon oxide film×1.45+the film thickness of the silicon nitride film×2.0=m+137.5 nm”.

In connection with the formation of the antireflection film, allowing the film thicknesses of the silicon oxide and nitride films to be freely combined is advantageous for the sensitivity characteristic and costs. For example, in the conventional structure, an antireflection film needs to be formed on the sidewall film by combining the silicon oxide film with the silicon nitride film. Thus, a deposition process and mask steps for the silicon oxide film need to be added in order to achieve a sensitivity characteristic of a desired value. This increases the number of steps required and is thus disadvantageous for process costs.

Furthermore, even the use of the conventional structure with only the sidewall film enables the desired antireflection film structure to be formed by laminating the silicon oxide film and the silicon nitride film. However, since an increase in the rate of the silicon oxide film reduces the rate of the silicon nitride film, when source/drain impurities are implanted, the size of the silicon oxide film, which is not so dense as the silicon nitride film, increases. Thus, the distribution of the silicon oxide film spreads to the channel portion to degrade the short channel characteristic.

The present invention has been made in view of the above-described conventional circumstances. An object of the present invention is to increase the operation speed of the peripheral digital circuit while inhibiting reflected light from the pixel portion to allow the sensitivity characteristic to be improved.

To accomplish the object, a method of manufacturing a MOS solid-state image device according to the present invention, the solid-state image device including a plurality of digital portions and pixel portions mixedly mounted on a semiconductor substrate, a peripheral circuit being formed in each of the digital portions, includes the steps of forming an isolation portion between each of the digital portions and a corresponding one of the pixel portions on the semiconductor substrate, forming a light receiving portion in a predetermined region of the pixel portion, forming a gate electrode on the semiconductor substrate in each of the digital portions and a region located adjacent to the light receiving portion in the pixel portion, via a gate insulating film, forming a detection portion in a region located adjacent to the light receiving portion in the pixel portion across the gate electrode formation region, depositing a silicon oxide film all over a resulting surface, selectively removing the silicon oxide film from the resulting surface so that the silicon oxide film is left on a side surface of the gate electrode, on the entire surface of the light receiving portion of the pixel portion, on a part of the isolation portion located adjacent to the light receiving portion, and on the gate electrode in the pixel portion to form a lower layer portion of an antireflection film on the light receiving portion and an inner layer portion of an offset sidewall in the digital portion at a time, forming an extension diffusion layer and a pocket layer in the digital portion through the gate electrode and the offset sidewall as a mask, forming a sidewall film all over a resulting surface by a CVD method, forming a cap film with a refractive index that is higher than that of the silicon oxide film and lower than that of the semiconductor substrate, on the sidewall film, and selectively removing the sidewall film and the cap film from the resulting surface so that the sidewall film and the cap film are left on a side surface of the offset sidewall, on the entire surface of the light receiving portion of the pixel portion, on the part of the isolation portion located adjacent to the light receiving portion, and on the gate electrode in the pixel portion to form an upper layer portion of the antireflection film on the light receiving portion and an outer layer portion of the offset sidewall in the digital portion at a time.

Furthermore, the offset sidewall film is an HTO film.

Furthermore, a deposition temperature for the HTO film is 700 to 800° C.

Furthermore, the cap film includes at least a silicon nitride film, and a deposition temperature for the silicon nitride film is 500 to 600° C.

Furthermore, a MOS solid-state image device according to the present invention includes a plurality of digital portions and pixel portions mixedly mounted on a semiconductor substrate, a peripheral circuit being formed in each of the digital portions, wherein a transistor portion of each of the digital portions includes a gate electrode formed on the semiconductor substrate via a gate insulating film, a plate-like offset sidewall formed on a side surface of the gate electrode, and a sidewall formed on a side surface of the offset sidewall, the pixel portion includes a light receiving portion formed in the semiconductor substrate, a detection portion for detecting a signal potential generated by the light receiving portion, a gate electrode formed between the light receiving portion and the detection portion on a surface of the semiconductor substrate via a gate insulating film, an antireflection film covering the light receiving portion, and a read circuit electrically connected to the detection portion, and the antireflection film is formed by laminating a cap film on components of the offset sidewall and the sidewall deposited in the digital portion, the cap film having a refractive index that is higher than that of a component of the offset sidewall and lower than that of the semiconductor substrate.

Furthermore, the component of the offset sidewall is a silicon oxide film.

Furthermore, a surface layer portion of the semiconductor substrate includes an extension diffusion layer and a pocket layer formed through the gate electrode and offset sidewall formed in the digital portion, as a mask.

Furthermore, the cap film used for the sidewall includes at least a silicon nitride film.

Furthermore, the antireflection film covers the side surface of the gate electrode and at least a gate electrode-side surface of a top portion of the gate electrode.

### BRIEF DESCRIPTION OF THE DRAWINGS

FIG. 1 is a schematic sectional view showing the structure of a MOS solid-state image device according to the present invention;

FIG. 2A is a sectional view showing a process of manufacturing a MOS solid-state image device according to the present invention;

FIG. 2B is a sectional view showing the process of manufacturing the MOS solid-state image device according to the present invention;

FIG. 2C is a sectional view showing the process of manufacturing the MOS solid-state image device according to the present invention;

FIG. 2D is a sectional view showing the process of manufacturing the MOS solid-state image device according to the present invention;

FIG. 3 is a schematic sectional view showing the structure of a conventional MOS solid-state image device; and

FIG. 4 is a schematic sectional view showing the structure of a conventional MOS solid-state image device including an antireflection film.

### DESCRIPTION OF THE EMBODIMENT

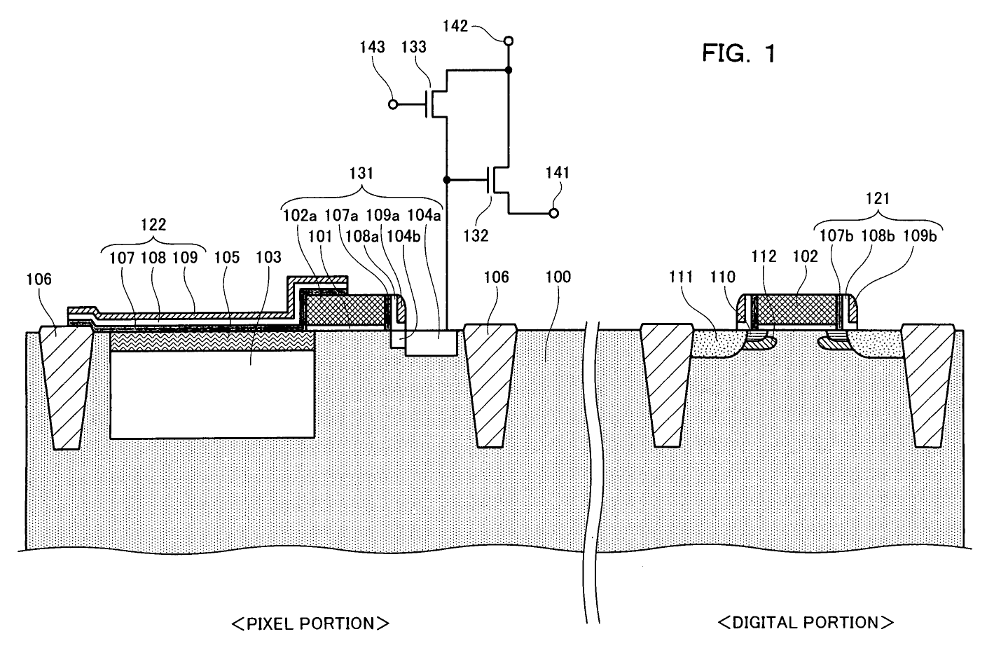

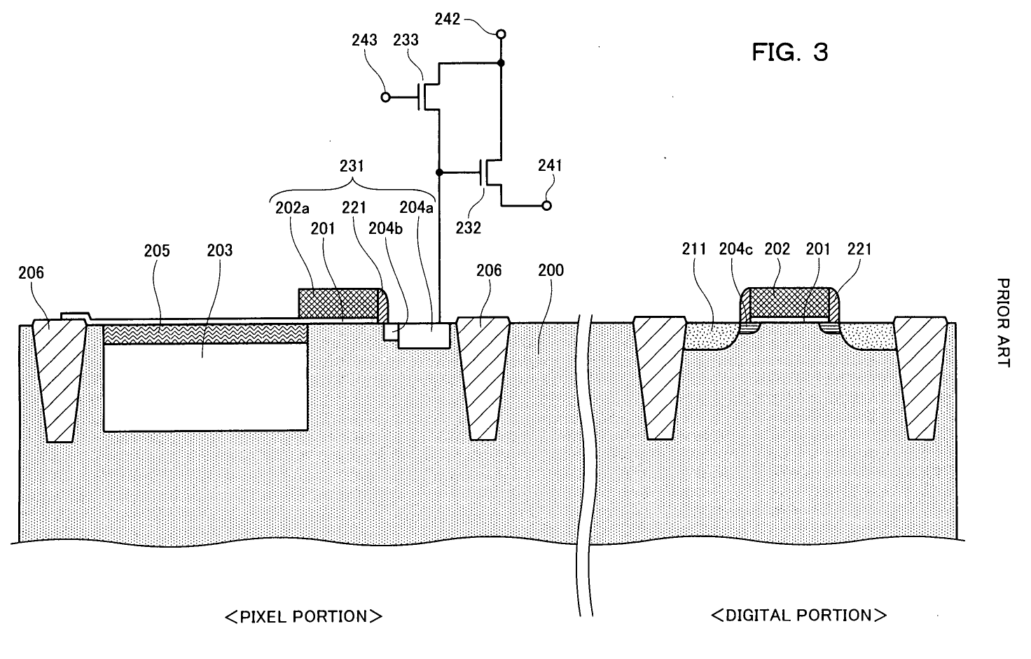

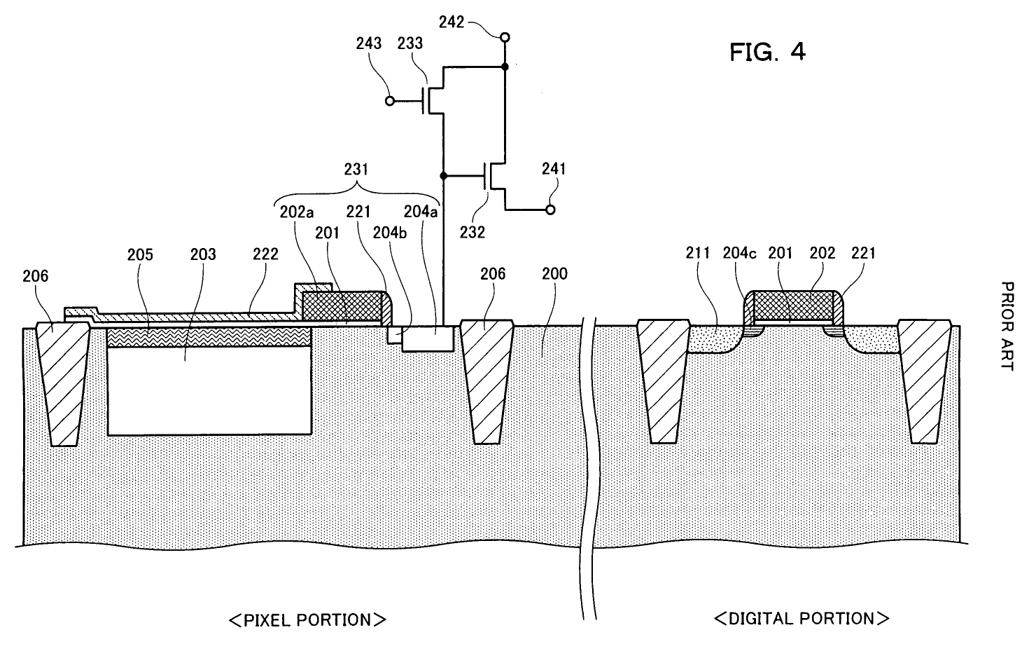

A MOS solid-state image device according to the present invention will be described below in detail with reference to the drawings. FIG. 1 is a schematic sectional view showing the structure of the MOS solid-state image device according to the present invention and showing the structure of a digital portion and a pixel portion in the MOS solid-state image device according to the present invention. Here, the present invention will be described based on a case in which the present invention is applied to the MOS solid-state image device in which an active read circuit is connected to a diffusion region in the pixel portion as in the case of the above-described conventional MOS solid-state image device.

Furthermore, the structure of the MOS solid-state image device will be described in brief in conjunction with, for example, an n-channel MOSFET with a polysilicon gate structure in the digital portion.

In the MOSFET structure in the digital portion, a gate insulating film 101 made up of a silicon oxide film and a gate electrode 102 made of polysilicon are formed on a substrate 100 made up of silicon, in this order from below. A plate-like offset sidewall film 107b is formed as a side surface of the gate electrode 102. A sidewall film 108b and a sidewall film 109b for the gate electrode of the digital portion are formed adjacent to the offset sidewall film 107b, in this order from the gate electrode 102 side; the sidewall film 108b is made up of a silicon oxide film, and the sidewall film 109b is made up of a silicon nitride film. A sidewall film 121 is thus formed which is made up of the offset sidewall film 107b, the sidewall film 108b, and the sidewall film 109b.

An n-type extension diffusion layer 110 is formed in a surface layer portion in the substrate 100 by implanting ions of phosphorous or arsenic through the gate electrode 102 and the offset sidewall film 107b as a mask. A p-type pocket layer 112 is formed under the n-type extension diffusion layer 110.

A source/drain diffusion layer 111 with a higher concentration than the extension diffusion layer 110 is formed in the surface layer portion in the substrate 100 and outside the extension diffusion layer 110 by implanting ions of phosphorous or arsenic through the gate electrode 102, the offset sidewall film 107b, and the sidewall film 121 as a mask.

Then, the structure of the pixel portion will be described in brief. This structural scheme transfers signal charges generated by a light receiving portion 103 using photoelectric conversion, from the light receiving portion 103 to a diffusion region 104a, and outputs a change in potential occurring in the diffusion region 104a.

A transferring transistor 131 is composed of the light receiving portion 103 as a source, the diffusion region 104a as a drain, and a gate electrode 102a (hereinafter referred to as a transfer gate electrode) provided on the surface of the semiconductor substrate 100 between the light receiving portion 103 and the diffusion region 104a via the insulating film 101.

The diffusion region 104a is electrically connected to a gate of an amplifying transistor 132 and a source of a resetting transistor 133 so as to make up floating diffusion. The diffusion region 104a is hereinafter referred to as the detection portion 104a. A drain of the amplifying transistor 132 and a drain of the resetting transistor 133 are both electrically connected to a power supply terminal 142 to which a power supply potential is supplied. The transistors operate similarly to those in the conventional MOS solid-state image device, described above.

Furthermore, although not shown in the drawings, a source of the amplifying transistor 132 is selectively connected to a ground potential via a load transistor and a load resistor. If the source of the amplifying transistor 132 is connected to the ground potential, a source follower is formed, and an output signal is output from an output terminal 141.

The light receiving portion 103 and the detection portion 104a are formed in the silicon substrate 100 by ion implantation or the like, as an N-type impurity region. The concentration of impurities in the light receiving portion 103 is preferably adjusted to about 1.0E12 cm⁻² to 1.0E13 cm⁻²; the concentration may be set to any other value as long as photoelectric conversion is possible at the value. Furthermore, the light receiving portion 103 is appropriately formed to a depth of about 0.5 to 2.0 μm from the surface of the substrate. In FIG. 1, a buried structure with a surface P-type layer 105 may be adopted as is the case with the conventional MOS solid-state image device. However, the present invention is applicable to a MOS solid-state image device without the surface P-type layer 105.

Meanwhile, the concentration of impurities in the detection portion 104a has only to allow Ohmic connection to be established through metal wiring, and is preferably at least 1.0E15 cm⁻². The detection portion 104a is appropriately formed to a depth of about 0.2 to 0.4 μm from the substrate surface.

Desirably, an offset sidewall 107a made up of a silicon oxide film is provided at a side end of the gate electrode in the detection portion 104a. Desirably, an N-type impurity diffusion region 104b (hereinafter referred to as an LDD diffusion region 104b) with a lower impurity concentration than the detection portion 104a is formed in the silicon substrate 100 and immediately below the offset sidewall 107a. The concentration of impurities in the LDD diffusion region 104b may be about 1.0E12 cm⁻² to 1.0E13 cm⁻². The LDD diffusion region 104b is formed by implantation through only the transfer gate electrode 102a as a mask rather than through both the offset sidewall 107a and the transfer gate electrode 102a as a mask.

In the MOS solid-state image device according to the present invention, an antireflection film 122 is formed. Here, the antireflection film 122 has a structure including a cap film made up of a silicon nitride film 109 covering at least the light receiving portion 103, and a silicon oxide film 107 and a silicon oxide film 108 formed by a CVD method and laminated under the cap film. The antireflection film 122 is formed to cover at least the light receiving portion 103 and may cover a side surface of the transfer gate electrode 102a, as well as a part of a top surface of the transfer gate electrode 102a, and a part of a top surface of an isolation portion 106 located adjacent to the light receiving portion 103.

As described above, the sidewall in the digital portion has a multilayer structure including the offset sidewall located inside, and the extension diffusion layer and the pocket layer are formed adjacent to the source/drain diffusion region through the offset sidewall and the gate electrode as a mask. This enables inhibition of hot carriers generated near the drain by a high electric field, while allowing for implantation of impurities of the same conductivity type as that of channel impurities. A region surrounding the source/drain portion can thus be doped at a high concentration, allowing extension of a depletion layer from the drain to be inhibited. This is effective against the inhibition of the short channel effect, enabling a reduction in gate length and an increase in the operation speed of the digital portion. For the pixel portion, the sidewall is formed simultaneously with formation of the antireflection film of the laminate structure in which the cap film in the uppermost layer is made up of a silicon nitride film. Thus, the antireflection film thickness can be optimized with the manufacturing process controlled to provide a high sensitive MOS solid-state image device. Thus, the present invention is particularly useful for high-grade single-lens reflex type digital still cameras, which require a high operation speed and a high S/N ratio, commercial-off-the-shelf and professional digital still camera solid-state image devices, and solid-state image devices for commercial-off-the-shelf and broadcasting equipment which are intended mainly for high vision motion pictures.

The structure in which both the extension diffusion layer and the laminate antireflection film are formed has been described. Either one of the arrangements may be provided so as to exert the corresponding one of the effects.

Now, a method of manufacturing a MOS solid-state image device in the form of a system on chip according to the present invention will be described.

FIGS. 2A, 2B, 2C, and 2D are sectional views showing a process of manufacturing a MOS solid-state image device according to the present invention. In particular, the digital portion will be described taking an n-channel MOSFET as an example.

First, as shown in FIG. 2A, the isolation portion 106 is formed in the silicon substrate 100 by a well-known trench isolation method. Thereafter, patterning is performed using a photo resist (not shown in the drawings), and arsenic is implanted at about 1.0E12 cm⁻² to 1.0E13 cm⁻² to form the light receiving portion 103.

Then, the gate insulating film 101 is formed on the silicon substrate 100 by a thermal oxidation method. A polysilicon film of 180 nm in thickness is deposited at 600 to 650° C. The polysilicon film is then patterned (not shown in the drawings) using a photo resist on the polysilicon film. Dry etching is then performed to form the gate electrode 102, the transfer gate electrode 102a, and the gate insulating film 101.

Then, as shown in FIG. 2B, patterning (not shown in the drawings) is performed using a photo resist so as to surround the light receiving portion 103. Boron is implanted into the light receiving portion 103 at about 1.0E12 cm⁻² to 1.0E13 cm⁻² to form the surface P-type layer 105 on the light receiving portion 103. Thereafter, patterning (not shown in the drawings) is performed using a photo resist to implant arsenic at about 1.0E12 cm⁻² to 1.0E13 cm⁻² to form the LDD diffusion region 104b of the detection portion.

Then, as shown in FIG. 2C, the offset sidewall film 107 is deposited by a CVD method. In this case, an HTO film of about 10 to 15 nm in film thickness is deposited all over the resulting surface at a deposition temperature of 700 to 800° C. Thereafter, patterning (not shown in the drawings) is performed using a photo resist, with the resist left on the entire surface of the light receiving portion 103 of the pixel portion, on a part of the isolation portion 106 and the transfer gate 102a, and on the sidewall of the gate electrode 102. Anisotropic dry etching is then performed to form offset sidewall films (107a and 107b) made up of HTO films, on the sidewalls of the transfer gate 102a and gate electrode 102 in the region covered with the resist.

In the digital portion, as measures against hot carriers, arsenic is implanted at about 1.0E14 cm⁻² to 1.0E15 cm⁻² at an acceleration voltage of 10 KeV or less through the formed offset sidewall film 107b and the gate electrode 102 as a mask to form the extension diffusion layer 110. At this time, the arsenic is not implanted into the pixel portion, which is covered with the photo resist (not shown in the drawings). Subsequently, the pocket layer 112 is formed for the following reason. When the concentration of p-type doping is high near opposite ends of a channel in the n-channel MOSFET, a high electric field component provided by the source and drain is cancelled by the p-type doping. To inhibit the cancellation to maintain the short channel effect, the pocket layer 112 is formed. The pocket layer 112 is formed simultaneously with the implantation of the extension diffusion layer 110 by implanting boron at about 1.0E12 cm⁻² to 1.0E13 cm⁻² at an acceleration voltage of 10 to 20 KeV. The extension diffusion layer 110 inhibits possible hot carriers, and the pocket layer 112 maintains the short channel effect. As a result, the operation speed of the digital portion can be increased.

Then, as shown in FIG. 2D, the silicon oxide film 108 is deposited all over the resulting surface to have a thickness of 30 nm or less at a deposition temperature of 600 to 700° C. by means of the CVD method. The silicon nitride film 109 is further deposited on the silicon oxide film to have a thickness of 40 to 70 nm at a deposition temperature of 500 to 600° C. Although the silicon nitride film is ordinarily deposited at a high deposition temperature of 700 to 800° C. by the CVD method, in this case, the silicon nitride film 109 is deposited at lower temperatures in order to inhibit the boron in the P-channel MOS portion from thermally diffusing to under the gate, thus improving the short channel characteristic. In this case, to maximize the effects of the antireflection film in the light receiving portion 103, the film thicknesses of the offset sidewall film 107, made up of the HTO film, the silicon oxide film 108, and the silicon nitride film 109 may be appropriately combined.

Then, patterning (not shown in the drawings) is performed using a photo resist, with the resist left on the entire surface of the light receiving portion 103 of the pixel portion, on a part of the isolation portion 106 and the transfer gate 102a, and on the side surface of the gate electrode 102. Thereafter, anisotropic dry etching is performed to form a three-layer structure on the sidewalls of the transfer gate 102a and gate electrode 102 in the region covered with the resist, the three-layer structure including the offset sidewall films (107a and 107b), made up of the HTO films, the silicon oxide films (108a and 108b), and the silicon nitride films (109a and 109b). At the same time, the antireflection film 122, formed of the offset sidewall film 107, the silicon oxide film 108, and the silicon nitride film 109, is formed on the light receiving portion 103.

Then, in the digital portion, with the offset sidewall film 107b and the sidewall films 108b and 109b formed on the side surface of the gate electrode 102, the sidewall film 108b being made up of the silicon oxide film and the sidewall film 109b being made up of the silicon nitride film, arsenic is implanted at about 1.0E15 cm⁻² to 1.0E16 cm⁻² at an acceleration voltage of 40 to 60 KeV to form the source/drain diffusion layer 111 in the case of an n-channel MOSFET. Likewise, in the pixel portion, with the offset sidewall film 107a and the sidewall films 108a and 109a formed on the detection portion-side side surface of the transfer gate 102a, the sidewall film 108a being made up of the silicon oxide film and the sidewall film 109a being made up of the silicon nitride film, arsenic is implanted at 1.0E15 cm⁻² or more at an acceleration voltage of 40 to 60 KeV to form the diffusion layer of the detection portion 104a. At this time, while the arsenic is being implanted into the pixel portion, the arsenic is not implanted into the digital portion, which is covered with the photo resist.

Finally, a BPSG (Boron-Phospho-Silicate-Glass) film is deposited by an atmospheric pressure CVD method so as to cover the silicon substrate 100, the gate electrode 102, the transfer gate 102a, and the isolation portion 106. Then, annealing is performed, for example, at 900° C. for 30 seconds to flatten a BPSG surface to form an interlayer insulating film and thus wiring. A technique for the subsequent steps is well-known and will thus not be described in detail.

As described above, the present invention provides the MOS solid-state image device which is in the form of a system on chip and based on a design rule of at most 0.13 um and which enables both increased operation speed and improved image quality. In the digital portion, the pocket layer 102 is formed. Thus, the impurities with the same conductivity type as that of the channel impurities are implanted into the pocket layer 102 to dope the region surrounding the source/drain portion with a high concentration. Consequently, extension of the depletion layer from the drain is inhibited. This enables formation of a transistor that offers an acceptable short channel characteristic in spite of a reduction in gate length. Furthermore, a factor degrading the reliability of the MOS transistor in connection with the miniaturization is the hot carrier problem in the gate insulating film. According to the present invention, the offset sidewall film 107b is formed, and the extension diffusion layer 110 is formed through the offset sidewall film 107b as a mask. Thus, the distribution of the concentration of impurities in the N-type layer near the drain has a gentle inclination. This mitigates an electric field acting parallel to the channel. Therefore, the hot carrier problem is also cleared.

The pixel portion can be created using the dedicated process optimized for the manufacture of the CCD solid-state image device. For example, an enhanced sensitivity characteristic is essential for improving the image quality. To achieve this, the antireflection film 122 with an optimum film thickness needs to be formed on the light receiving portion 103. To maximize the effects of the antireflection film 122, the film thickness to which the antireflection film 122 is formed needs to be optimized. For example, a silicon oxide film of 5 to 20 nm in film thickness and a silicon nitride film of 40 to 60 nm in film thickness are optimum for the effects of the antireflection film. Furthermore, the antireflection film is composed of the silicon oxide films 107 and 108 and the silicon nitride film 109. The silicon oxide films 108 and 109, formed as a sidewall, allow the film composition ratio thereof to be freely adjusted and thus offer a high degree of freedom of design. Thus, the need to add a process of depositing a silicon oxide film or a mask process is eliminated, enabling a reduction in the number of steps required. This is advantageous for process costs.

The active MOS solid-state image device has been illustrated and described which is in the form of a system on chip made up of the digital portion and the pixel portion including the detection portion to which the read circuit that is an amplifying circuit with an amplifier is connected. However, the above-described configuration also does not limit the technical scope of the present invention.

Any configuration can be adopted for the circuit form of each pixel in the pixel portion of the MOS solid-state image device provided that the pixel includes the light receiving potion, the diffusion region, the gate electrode formed on the surface of the semiconductor substrate between the light receiving portion and the diffusion region, and the read circuit connected to the light receiving portion or the diffusion region. For example, the present invention is applicable to a passive MOS solid-state image device including no amplifier in the read circuit in the pixel or a MOS solid-state image device with the read circuit connected directly to the light receiving portion. In the MOS solid-state image device with the read circuit connected directly to the light receiving portion, the gate electrode functions as a gate electrode of the resetting transistor, and the diffusion region functions as a drain of the resetting transistor.

What is claimed is:

1. A method of manufacturing a MOS solid-state image device including a plurality of digital portions and pixel portions mixedly mounted on a semiconductor substrate, a peripheral circuit being formed in each of the digital portions, comprising the steps of:
forming an isolation portion between each of the digital portions and a corresponding one of the pixel portions on the semiconductor substrate;
forming a light receiving portion in a predetermined region of the pixel portion;
forming a gate electrode on the semiconductor substrate in each of the digital portions and a region located adjacent to the light receiving portion in the pixel portion, via a gate insulating film;
forming a detection portion in a region located adjacent to the light receiving portion in the pixel portion across the gate electrode formation region;
depositing a silicon oxide film all over a resulting surface;
selectively removing the silicon oxide film from the resulting surface so that the silicon oxide film is left on a side surface of the gate electrode, on an entire surface of the light receiving portion of the pixel portion, on a part of the isolation portion located adjacent to the light receiving portion, and on the gate electrode in the pixel portion to form a lower layer portion of an antireflection film on the light receiving portion and an inner layer portion of an offset sidewall in the digital portion at a time;
forming an extension diffusion layer and a pocket layer in the digital portion through the gate electrode and the offset sidewall as a mask;
forming a sidewall film all over a resulting surface by a CVD method;
forming a cap film with a refractive index that is higher than that of the silicon oxide film and lower than that of the semiconductor substrate, on the sidewall film; and
selectively removing the sidewall film and the cap film from the resulting surface so that the sidewall film and the cap film are left on a side surface of the offset sidewall, on the entire surface of the light receiving portion of the pixel portion, on the part of the isolation portion located adjacent to the light receiving portion, and on the gate electrode in the pixel portion to form an upper layer portion of the antireflection film on the light receiving portion and an outer layer portion of the offset sidewall in the digital portion at a time.

2. The method of manufacturing the MOS solid-state image device according to claim 1, wherein the offset sidewall film is an HTO film.

3. The method of manufacturing the MOS solid-state image device according to claim 2, wherein a deposition temperature for the HTO film is 700 to 800° C.

4. The method of manufacturing the MOS solid-state image device according to claim 1, wherein the cap film includes at least a silicon nitride film, and a deposition temperature for the silicon nitride film is 500 to 600° C.

5. A MOS solid-state image device comprising a plurality of digital portions and pixel portions mixedly mounted on a semiconductor substrate, a peripheral circuit being formed in each of the digital portions,
wherein a transistor portion of each of the digital portions comprises a gate electrode formed on the semiconductor substrate via a gate insulating film, a plate-like offset sidewall formed on a side surface of the gate electrode, and a sidewall formed on a side surface of the offset sidewall,
the pixel portion comprises a light receiving portion formed in the semiconductor substrate, a detection portion for detecting a signal potential generated by the light receiving portion, a gate electrode formed between the light receiving portion and the detection portion on a surface of the semiconductor substrate via a gate insulating film, an antireflection film covering the light receiving portion, and a read circuit electrically connected to the detection portion, and
the antireflection film is formed by laminating a cap film on components of the offset sidewall and the sidewall deposited in the digital portion, the cap film having a refractive index that is higher than that of a component of the offset sidewall and lower than that of the semiconductor substrate.

6. The MOS solid-state image device according to claim 5, wherein the component of the offset sidewall is a silicon oxide film.

7. The MOS solid-state image device according to claim 5, wherein a surface layer portion of the semiconductor substrate includes an extension diffusion layer and a pocket layer formed through the gate electrode and offset sidewall formed in the digital portion, as a mask.

8. The MOS solid-state image device according to claim 5, wherein the cap film used for the sidewall includes at least a silicon nitride film.

9. The MOS solid-state image device according to claim 7, wherein the cap film used for the sidewall includes at least a silicon nitride film.

10. The MOS solid-state image device according to claim 5, wherein the antireflection film covers the side surface of the gate electrode and at least a gate electrode-side surface of a top portion of the gate electrode.
